(19) United States
(12) Patent Application Publication
(10) Pub. No.: US 2025/0172978 A1
(43) Pub. Date: May 29, 2025

(54) LEAKAGE-BASED ON-CHIP TEMPERATURE PROFILING SYSTEM

(71) Applicant: Synopsys, Inc., Sunnyvale, CA (US)

(72) Inventor: Ketul Bhogilal Sutaria, Austin, TX (US)

(21) Appl. No.: 18/523,504

(22) Filed: Nov. 29, 2023

(51) Int. Cl. G06F 1/20; H03K 3/03; H03K 17/687

(52) U.S. Cl. CPC G06F 1/206; H03K 17/6872; H03K 3/0315

(57) ABSTRACT

Digital ring oscillators (DROs) are distributed throughout an integrated circuit die to achieve localized temperature sensing with a small form factor. A DRO can include cross-coupled inverters, header and footer transistors, and delay elements. Leakage current through the DRO causes a state of an internal node to toggle at a frequency that is a function of temperature of the DRO, which can depend on temperature of a nearby circuit (e.g., a processor). The integrated circuit die may include a controller that is coupled to the DROs. The controller can receive oscillatory digital signals produced by the DROs and control operation of the integrated circuit die based on temperatures indicated by the frequencies of the oscillatory digital signals.

### TECHNICAL FIELD

The present disclosure generally relates to a temperature monitoring system. In particular, the present disclosure relates to in-situ monitoring of temperature in integrated circuits.

### BACKGROUND

With the advent of energy efficient techniques like dynamic voltage and frequency scaling (DVFS) on multi-core CPUs and densely populated system-on-chips (SoCs), on-die temperature measurement is becoming more important. Localized hot-spots are becoming more common due to the increase in processing units on a single integrated circuit die, and those localized hot-spots are getting hotter faster. For example, advanced technology nodes using backside power delivery and Gate-all-around FETs (GAAFETs) have very low thermal dispersion capability. The latent heat from localized hot-spots from high performance silicon causes increase in leakage current in energy efficient cores, which creates a positive feedback effect (i.e., thermal runaway). Left unmonitored, thermal runaway can lead to catastrophic failure.

Devices like laptops or phones have processing cores that operate at different frequencies, which necessitates different workload balancing based on local thermal limits. To control workloads, a process management system measures the temperature on the chip and controls workloads based on those measured temperatures. Localized temperature can be important considering differences in core workloads (i.e., different cores might be operating at different temperatures). Some temperature sensing solutions may require significantly larger area on the chip. For example, an image processing chip, which needs space for important processing units, may reserve a significant amount of space (e.g., half the chip) for a temperature sensing solution. Because of this large size, a temperature sensing solution measures temperatures across a larger area that may not be accurately representative of localized hot-spot temperatures. Further, some temperature sensing solutions produce analog signals, which need to be shielded, have a very high area overhead, need time expensive dedicated manual routing efforts, and need to be converted into digital signals. This conversion requires a space-consuming analog to digital converter for post processing. Some temperature sensing solutions may also require a dedicated power source to operate. For example, one solution is a bandgap reference circuit, which contributes to the chip's power overhead. Thus, such temperature sensing solutions may have a large chip area, be inaccurate, and be power inefficient.

### SUMMARY

In one aspect, a digital ring oscillator includes a pair of cross coupled inverters, two header transistors coupled between a supply voltage and the inverters, two footer transistors coupled between the inverters and ground, and delay elements coupled to the inputs of the header and footer transistors and outputs of the inverters. An input of each of the inverters is coupled to an output of the other inverter at one of two complementary state nodes. The header transistors gate a connection of the supply voltage to the inverters. Footer transistors gate a connection of the inverters to ground. Delay elements are coupled between the state nodes and gates of the header and footer transistors. The state nodes toggle states as a result of leakage current gated by the header transistors from the supply voltage through the inverters to the state nodes, and as a result of leakage current gated by the footer transistors from the state nodes through the inverters to ground. The frequency of the toggling is a function of the leakage currents, and the leakage currents are a function of a temperature of the digital ring oscillator.

In another aspect, a controller receives oscillatory digital signals (e.g., clock-like digital signals) from sensor blocks on an integrated circuit die. Frequencies of the oscillatory digital signals vary as a function of temperature. The controller controls operation of circuitry on the integrated circuit die based on temperatures indicated by the frequencies of the oscillatory digital signals.

Other aspects include components, devices, systems, improvements, methods, processes, applications, computer readable mediums, and other technologies related to any of the above.

### BRIEF DESCRIPTION OF THE DRAWINGS

The disclosure will be understood more fully from the detailed description given below and from the accompanying figures of embodiments of the disclosure. The figures are used to provide knowledge and understanding of embodiments of the disclosure and do not limit the scope of the disclosure to these specific embodiments. Furthermore, the figures are not necessarily drawn to scale.

FIG. 1 is a block diagram of an integrated circuit with built-in temperature sensor blocks, in accordance with some embodiments of the present disclosure.

FIG. 2A is a schematic diagram of a unit cell of a temperature sensor block, in accordance with some embodiments of the present disclosure.

FIG. 2B is a diagram showing the states of switches of the unit cell of FIG. 2A, in accordance with some embodiments of the present disclosure.

FIG. 3A is a simplified representation of the unit cell of FIG. 2A, in accordance with some embodiments of the present disclosure.

FIG. 3B is a diagram showing the states of switches in the simplified representation of FIG. 3A, in accordance with some embodiments of the present disclosure.

FIG. 4 depicts a digital ring oscillator (DRO), in accordance with some embodiments of the present disclosure.

FIG. 5 depicts a timing diagram of the inputs, outputs, and transistor states, of the DRO of FIG. 4, in accordance with at least one embodiment.

FIG. 6 is a flow diagram of various processes used during the design and manufacture of an integrated circuit in accordance with some embodiments of the present disclosure.

FIG. 7 is a block diagram of an example computer system in which embodiments of the present disclosure may operate.

### DETAILED DESCRIPTION

Aspects of the present disclosure relate to a leakage-based on-chip temperature profiling system. Temperature measurement is important to detecting overheating chips and preventing catastrophic failure. Digital ring oscillators (DROs) described herein may produce a digital oscillatory signal with a frequency that is a function of temperature. The oscillation frequency is a function of leakage current, and the leakage current is a function of temperature. For digital circuits, using a digital ring oscillator to measure temperature is advantageous because the output of a digital ring oscillator does not require an analog to digital converter (ADC) to be interpreted by a processing unit or controller unit on the digital circuit and also avoids expensive shielded routes. By contrast, some temperature sensing designs may produce an analog output and thus, require an ADC on the chip. Therefore, utilizing a digital ring oscillator is space efficient not only because space is not needed for the ADC to convert the digital ring oscillator's output, but also because the footprint of a digital ring oscillator is substantially less than some temperature sensing designs (e.g., a bandgap reference circuit). Moreover, by leveraging leakage current to determine temperature, the digital ring oscillator does not add to the chip's power overhead.

The relatively small form factor of the DROs also provide an increased accuracy in measuring localized hot-spot temperatures that a larger temperature sensor could not measure. Multiple DROs can be placed proximal to a single processing unit to measure the temperature at different locations on the single processing unit. This fine granularity can be expanded with the placement of one or more DROs at various processing units in a single integrated circuit die to determine an on-die temperature profile that has a finer measurement granularity than one, large temperature sensor could provide.

The digital ring oscillator described herein is also advantageous from an ease-of-use perspective. Compared to some solutions that require particular care during placement in a circuit layout (e.g., creating a boundary around the temperature sensing circuit), the present digital ring oscillator is similar to a more interchangeable switching element. Thus, commercial compilers may be capable of automatically replacing a temperature sensor circuit with the present digital ring oscillator.

The present temperature sensing system also increases processing thread management efficiency by taking action based on monitored temperature without an extra step of converting the temperature sensor block's output from analog to digital. The digital ring oscillator's output is already digital. The benefits of not needing an ADC to convert the present temperature sensor include saving space on the chip that would otherwise be needed for the ADC, not waiting the time that would otherwise be needed to convert the analog output to a digital one, and reducing the power consumption that the ADC would otherwise demand. One or more frequency dividers or time-to-digital converters may be used in combination with the digital ring oscillator rather than using an ADC, which has a larger footprint than either a frequency divider or the time-to-digital converter.

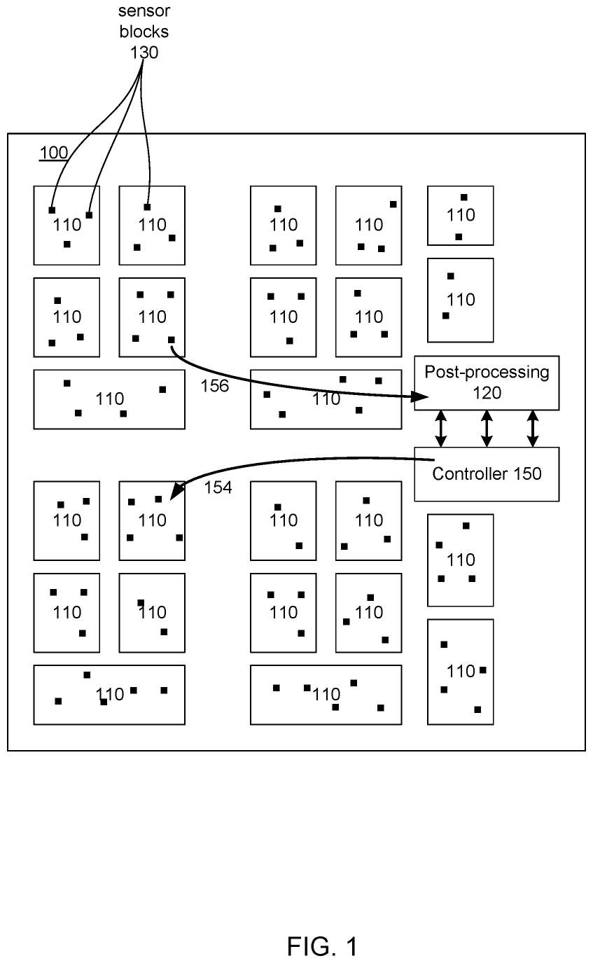

In more detail, FIG. 1 is a block diagram of an integrated circuit 100 with built-in temperature sensor blocks 130, in accordance with some embodiments of the present disclosure. Each sensor block may include a DRO which produces a frequency that is dependent on nearby temperature (e.g., temperature detected within a threshold range), which affects leakage current through the DRO. The built-in sensor blocks 130 allow for a fine-grained temperature sensing system. The sensor blocks 130 can have a relatively small form factor (e.g., smaller than standard cells such as flip-flops or latches). Each sensor block 130 may be a standard library cell design, allowing for unconstrained placement of cells with multiple instantiations. Multiple instantiations of the sensor blocks 130 allows for faster detection of localized hot-spots on the integrated circuit 100. The sensor blocks 130 operate on leakage-based temperature sensing principles. The sensor blocks 130 are sensitive to temperature variations and less sensitive to process and voltage variations.

In this particular example, the integrated circuit 100 contains different functional blocks 110. Examples could include processor cores, on-chip memory, input/output (I/O) interfaces, other types of logic, and analog and mixed signal circuits. Examples of processor cores include an energy-efficient core, performance core, a computer processing unit (CPU), or a neural engine.

The integrated circuit 100 also includes temperature sensor blocks, shown as small black squares some of which are labeled 130, and a corresponding controller 150. The sensor blocks 130 are distributed throughout the integrated circuit in order to monitor temperature at different points across the integrated circuit. The sensor blocks 130 are proximal to the functional blocks 110. Temperature may be monitored by circuits, such as a digital ring oscillator with frequency that varies as a function of temperature. For example, transistor leakage current of the digital ring oscillator is amplified with a modified digital gate and converted into an oscillatory digital signal that is correlated to on-die temperature. The distribution of sensor blocks 130 shown in FIG. 1 is not intended to be limiting. Different distributions of sensor blocks 130 will be apparent. The number of sensor blocks 130 on the integrated circuit die may be greater than the number of controller(s) 150 on the integrated circuit die.

In some embodiments, a post-processing unit 120 and a sensor controller 150 are also integrated on-chip. In FIG. 1, they are shown as two separate blocks and implemented in a distributed fashion, but in some embodiments, their functions may be performed by a single block (e.g., the controller 150 performs functions of the post-processing unit 120 as well). The post-processing unit 120 and/or the controller 150 communicates with the sensor blocks 130. The post-processing unit 120 and/or the controller 150 may send control signals to configure the sensor blocks 130 (e.g., send input signals causing the sensor blocks 130 to output data 156). The controller 150 may be a dynamic voltage and frequency scaling (DVFS) controller.

The post-processing unit 120 may receive data 156 from the sensor blocks 130. The data 156 may include an oscillating digital signal (“oscillatory digital signal” or “oscillating signal”) with a frequency that is indicative of a temperature at a local spot on the integrated circuit 100 (e.g., at a functional block or a localized area of a functional block). Each sensor block 130 may provide this oscillating signal in the data 156 to the post-processing unit 120. The post-processing unit 120 may determine the frequency of the oscillating signal using a frequency divider, frequency counter, or time-to-digital converter. The post-processing unit 120 may include one or more of such units for determining the frequencies of oscillating signals received. For example, the post-processing unit 120 may include ten frequency dividers to determine ten different oscillating signals from ten different sensor blocks 130.

The post-processing unit 120 may perform a comparison and/or mapping to determine a temperature corresponding to the received oscillating signal. In one example of determining temperature, the post-processing unit 120 accesses a register file that includes a mapping of frequencies to temperatures. In some embodiments, multiple register files may be accessible, where different register files correspond to different types of processing units (i.e., different operating frequencies of processing units). The post-processing unit 120 may look-up a temperature that maps to a determined frequency of an oscillating signal. In another example of determining temperature, the post-processing unit 120 uses a combination of comparison and mapping. The post-processing unit 120 may compare the received frequencies to a reference frequency. The reference frequency may be in a similar range at which the sensor blocks 130 operate (e.g., a range from a few kilohertz to one gigahertz). The reference frequency may be stored in a register file accessible by the post-processing unit 120. The post-processing unit 120 may be pre-calibrated to obtain an absolute temperature based on the difference between the received and reference frequencies, where the pre-calibration involves a look-up table in a register file storing data (e.g., empirical or simulated) for temperature comparisons. For example, the post-processing unit 120 may access a register file that includes a mapping of frequency differentials (i.e., relative to the reference frequency) and temperatures. The post-processing unit 120 may then determine a temperature through a look-up method. Additionally, or alternatively, the post-processing unit 120 may compare the received frequencies to each other to determine differentials between the received frequencies. The post-processing unit 120 may provide the results of these comparisons to the controller 150.

In some cases, the controller 150 may provide some analysis of the received data 156. For example, the controller 150 may determine an on-die temperature profile using differentials between frequencies of oscillating signals of the sensor blocks 130. The controller 150 may determine control signals 154 based on the data 156 output by the sensor blocks 130. The control signals 154 may include instructions to enable or disable throttling at a functional block. For example, the controller 150 may determine to enable voltage or clock throttling at a functional block in response to the data 156 indicating there is a localized hot-spot at the functional block. In this example, the controller 150 may also determine to disable voltage or clock throttling in response to the data 156 indicating there is no localized hot-spot. The control signals 154 may include instructions allocating processing threads among processing units of the functional blocks 110 based on the data 156 (e.g., based on comparisons of frequencies determined by the post-processing unit 120). The controller 150 may send control signals 154 to the functional blocks 110. In response to determining a temperature of an identified local hot-spot is below a threshold temperature, the controller 150 may disable voltage throttling at the integrated circuit die. In response to determining a temperature of an identified local hot-spot is above a threshold temperature, the controller 150 may enable voltage throttling at the integrated circuit die.

Temperature monitoring across different conditions (e.g., supply voltages and operating frequencies) and over time can be used to predict future failures before they occur, as part of the overall life cycle management for the device. The post-processing unit 120 or the controller 150 may provide the monitored oscillation frequencies, the on-die temperature profile, and/or the determined temperatures at localized areas on the die to a monitoring system. The monitoring system may include multiple instantiations of the post-processing unit 120 and/or the controller 150 across multiple integrated circuit dies. The collection of data from sensor blocks across various functional blocks across various integrated circuit dies allows the monitoring system to identify trends and correlations across a device (e.g., a smartphone) as a whole. The monitoring data may be analyzed on-chip (e.g., at a controller 150). Alternatively, or additionally, the data may be analyzed off-chip. For example, more complex analysis may require computational resources that are not available on-chip, and storage of monitored data indicative of localized temperatures captured over long periods of time may require more space than is available on-chip. Analysis may also combine the monitored data with other data that is not available on-chip, for example external measurements of power consumption. As another example, monitoring data from multiple chips may be analyzed together to provide a view of a board, a rack-mounted device or other environment that is larger than just a single chip.

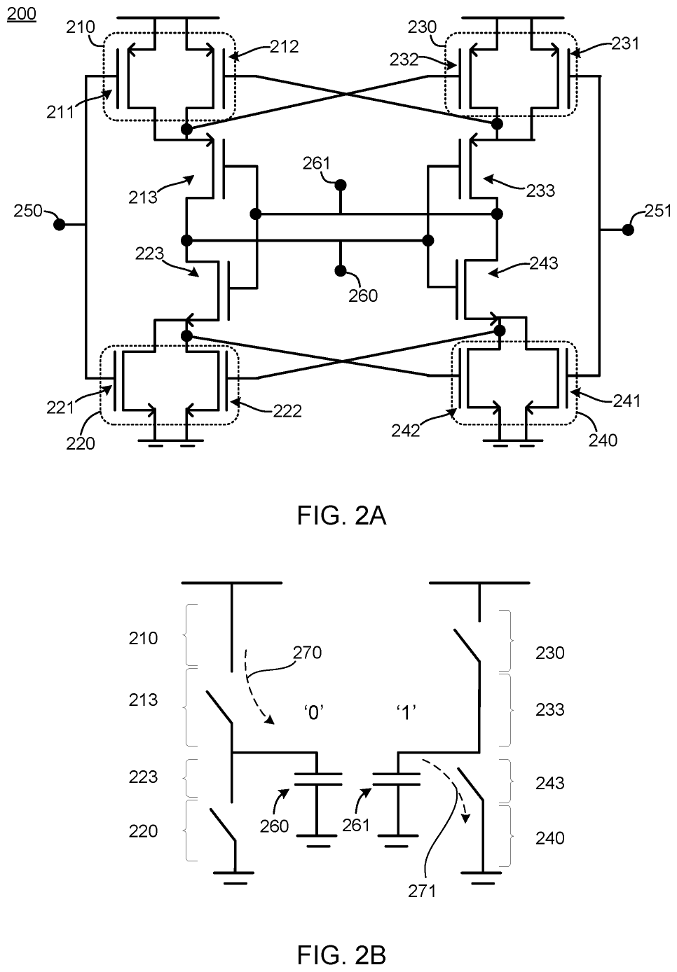

FIG. 2A is a schematic diagram of a unit cell of a temperature sensor block, in accordance with some embodiments of the present disclosure. FIG. 2B is a diagram showing one embodiment of the states of switches of the unit cell of FIG. 2A. FIG. 2B further shows preferred leakage paths according to the embodiment shown. The leakage paths cause internal nodes of the unit cell to charge and discharge, creating an oscillating signal which frequency is indicative of a temperature impacting the unit cell (e.g., temperature of a functional block to which the unit cell is proximate).

The unit cell 200 includes p-channel metal oxide semiconductor (PMOS) header transistors 210 and 230, n-channel metal oxide semiconductor (NMOS) footer transistors 220 and 240, and cross-coupled inverters (transistors 213/223 and 233/243). The PMOS header transistors 210 and 230 are cross-coupled. That is, the gate of transistor 212 is coupled to the drain of the transistor 232 and the gate of the transistor 232 is coupled to the drain of transistor 212. Similarly, the NMOS footer transistors 220 and 240 are cross-coupled. That is, the gate of the transistor 222 is coupled to the drain of the transistor 242 and the gate of the transistor 242 is coupled to the drain of the transistor 222. The PMOS header transistors may be referred to as a PMOS header and the NMOS footer transistors may be referred to as an NMOS footer. The total number of transistors of the unit cell 200 is twelve transistors.

The cross-coupled inverters include a first inverter configured with PMOS transistor 213 and NMOS transistor 223 and a second inverter configured with PMOS transistor 233 and NMOS transistor 243. The inverters are cross-coupled due to the input of each inverter being coupled to an output of the other inverter. The PMOS headers 210 and 230 gate a connection of a supply voltage to the cross-coupled inverters. The NMOS footers 220 and 240 gate a connection of the cross coupled inverters to ground.

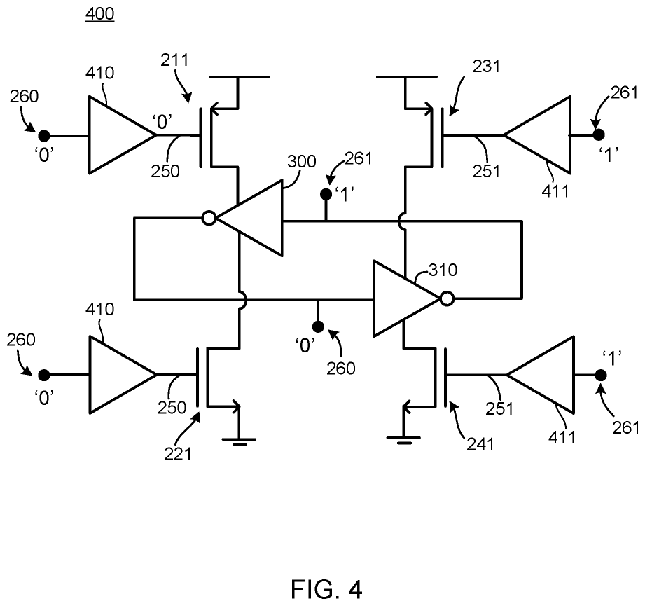

The cross-coupled inverters form a bistable circuit with state nodes 260 and 261 that are in complementary states. The first state node 260 is the output of the first inverter and the input to the second inverter. The second state node 261 is the output of the second inverter and the input to the first inverter. The state nodes 260 and 261 are connected to nodes 250 and 251, respectively, by delay elements as further described with respect to FIG. 4.

The PMOS header 210 is composed of two PMOS transistors 211 and 212 connected in parallel. Similarly, the PMOS header 230 is composed of two PMOS transistors 231 and 232 connected in parallel. The NMOS footer 220 is composed of two NMOS transistors 221 and 222 connected in parallel. Similarly, the NMOS footer 240 is composed of two NMOS transistors 241 and 242 connected in parallel. The source of the PMOS transistor 213 is coupled to the drains of the PMOS transistors 211 and 212. The NMOS transistor 223 is coupled to the drain of the PMOS transistor 213 and the drains of the NMOS transistors 221 and 222. The source of the PMOS transistor 233 is coupled to the drains of the PMOS transistors 231 and 232. The gate of the PMOS transistor 232 is coupled to the drains of PMOS transistors 211 and 212. The drains of the PMOS transistors 231 and 232 are coupled to the gate of the PMOS transistor 212. The NMOS transistor 243 is coupled to the drain of the PMOS transistor 233 and the drains of the NMOS transistors 241 and 242. The gate of the NMOS transistor 242 is coupled to the drains of the NMOS transistors 221 and 222. The drains of the NMOS transistors 241 and 242 are coupled to the gate of the NMOS transistor 222.

The transistors 212, 222, 232, and 242 serve to maintain voltage stability at the unit cell 200. The transistors 212, 222, 232, and 242 maintain a full voltage swing and prevent floating nodes at the header and footer transistors (e.g., the drain terminals at the PMOS headers or the drain terminals at the NMOS footers). The transistors 211, 221, 231, and 241 in combination with the cross coupled inverters (composed of transistors 213, 223, 233, and 243) serve to provide temperature sensing characteristics of the unit cell 200.

Sensing the temperature experienced at the unit cell 200 depends on leakage current through the inverter transistors 213, 223, 233, and 243. For example, the state node 261 discharges from ‘1’ to ‘0’ as current leaks through the inverter transistor 243 (at an OFF state) to ground through the NMOS footer 240 (at an ON state). In this same example, the state node 260 charges from ‘0’ to ‘1’ as current leaks through the transistor 213 (at an OFF state) to the state node 260 from VDD through the PMOS header 210 (at an ON state). This example of leakage currents is depicted in FIG. 2B.

In another example, the state node 261 charges from ‘0’ to ‘1’ as current leaks through the transistor 233 (at an OFF state) to the state node 261 from VDD through the PMOS header 230 (at an ON state). In this same example, the state node 260 discharges from ‘1’ to ‘0’ as current leaks through the transistor 223 (at an OFF state) to ground through the NMOS footer 220 (at an ON state). The charging and discharging of any given state node constitutes a state toggling at that internal node. As described above, this toggling is a result of leakage current gated by header transistors 210 and 230 from the supply voltage through the cross-coupled inverters to the state nodes 260 and 261, respectively. The toggling is also a result of leakage current gated by the footer transistors 220 and 240 from the state nodes 260 and 261, respectively, through the cross-coupled inverters to ground. The leakage current is a function of temperature, so the frequency of the toggling is a function of temperature.

FIG. 2B is a diagram showing one embodiment of the states of switches of the unit cell 200 of FIG. 2A. Additionally, FIG. 2B shows leakage paths based on the switches' states. In this example, the value at the input 250 is ‘0’ (logic low state) and the value at the input 251 is ‘1’ (logic high state). These inputs cause the PMOS header transistors 210 to be ON, the NMOS footer transistors 220 to be OFF, the PMOS transistor 213 to be OFF, and the NMOS transistor 223 to be ON. These ON and OFF states are shown in FIG. 2B as closed and open switches, respectively. This configuration of transistor switch states favors leakage current 270 from supply to state node 260, which is represented in FIG. 2B as a capacitor. The state node 260 is at a ‘0’ state until leakage current charges the state node 260 to a ‘1’ state.

On the right side of the unit cell 200, the ‘0’ at input 250 and ‘1’ at input 251 causes a complementary switch state. That is, these inputs cause the PMOS header 230 to be OFF, the NMOS footer 240 to be ON, the PMOS transistor 233 to be ON, and the NMOS transistor 243 to be OFF. This configuration causes the state node 261 in a ‘1’ state to start discharging due to leakage current 271 through NMOS transistor 243 to ground. The state node 261 is represented similar to the state node 260 by a capacitor in FIG. 2B.

The charging of state node 260 to logic high and the discharging of the state node 261 to logic low cause the cross-coupled inverters of the unit cell 200 to flip. The cross-coupled inverters provide a high gain to toggle the unit cell 200. This toggling can correspond (e.g., be proportional) to either one of the leakage currents 270 and 271 through the unit cell 200. These leakage currents 270 and 271 are correlated to temperature proximal to the unit cell 200 (e.g., temperature of a processing unit the unit cell 200 is located next to). The correlation between temperature and leakage current includes a greater leakage current with an increase in temperature, and a smaller leakage current with a decrease in temperature.

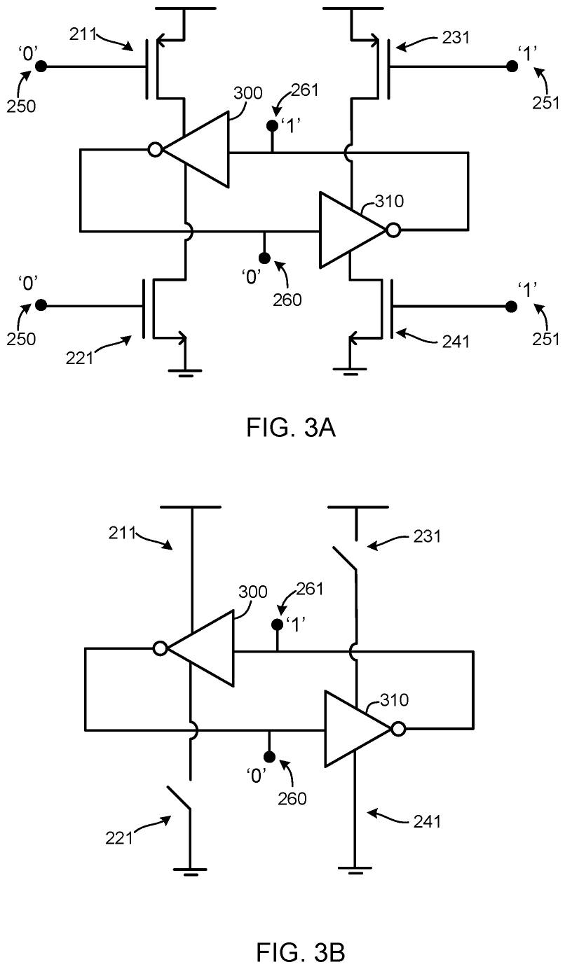

FIG. 3A is a simplified representation of the unit cell 200 of FIG. 2A, in accordance with one embodiment. The PMOS transistor 213 and the NMOS transistor 223 are represented by an inverter 300. The state node 261 is depicted as the input to the inverter 300. The PMOS transistor 233 and the NMOS transistor 243 are represented by an inverter 310. The state node 260 is depicted as the input to the inverter 310. The transistors 211, 221, 231, and 241 are depicted due to their use for temperature sensing. Although the transistors 212, 222, 232, and 242 are not depicted and may be excluded without necessarily sacrificing the temperature sensing capability of the unit cell 200, the transistors 212, 222, 232, and 242 maintain voltage stability. That is, the transistors 212, 222, 232, and 242 are included in the unit cell 200 to prevent floating nodes and encourage full voltage swings at those nodes.

Ignoring the delay elements for the moment, the states of inputs 250 and 251 at the unit cell 200 are coupled to the states of internal nodes 260 and 261, respectively, of the cross-coupled inverters 300 and 310. For example, a state of ‘0’ at the input 250 is the result of the state of ‘0’ stored at the state node 260. Similarly, a state of ‘1’ at the input 251 is the result of the state of ‘1’ stored at the state node 261. The toggling frequency (i.e., the oscillation signal output by the DRO) of any of these nodes 250, 251, 260, 261 is a function of the leakage current through the unit cell 200.

Additionally, the states of the inputs 250 and 251 at the unit cell 200 are complementary to the states of the internal nodes 260 and 261. For example, a state of ‘0’ at the input 250 is complementary to the state of ‘1’ stored at the internal node 261. Similarly, a state of ‘1’ at the input 251 is complementary to the state of ‘0’ stored at the internal node 260. This complementary logic creates a preferred least resistance path from power supply VDD to an internal node or from the internal node to ground. In one example of a creation of a preferred least resistance path, the internal node 261 is discharging from ‘1’ to ‘0’ through the NMOS transistor 243 and leakage current from the PMOS header 230 is not offsetting this discharge. In this example, the intermediate node between the PMOS header 230 and the PMOS transistor 233 is at VDD and the internal node 261 is also at VDD due to its initial state of ‘1’. Thus, the source-drain voltage for the PMOS header 230 and the transistor 233 are both 0 V, creating a high resistive path that current will not naturally follow. Thus, the natural leakage path for current is through the NMOS transistor 243, causing the internal node 261 to discharge.

FIG. 3B is a diagram showing the states of switches in the simplified representation of FIG. 3A, in accordance with some embodiments of the present disclosure. The PMOS transistor 211 is depicted as a closed switch in response to the ‘0’ input at the gate of the PMOS transistor 211. The NMOS transistor 221 is depicted as an open switch in response to the ‘0’ input at the gate of the NMOS transistor 221. The state node 260 at a state ‘O’ may be charged to ‘1’ as a result of leakage current, gated by the header transistor 211, from the supply voltage through the inverter 300 to the state node 260. The PMOS transistor 231 is depicted as an open switch in response to the ‘1’ input at the gate of the PMOS transistor 231. The NMOS transistor 241 is depicted as a closed switch in response to the ‘1’ input at the gate of the NMOS transistor 241. The state node 261 at a state ‘1’ may discharge to ‘0’ as a result of leakage current, gated by the footer transistor 241 through the inverter 310 to ground.

FIG. 4 depicts a digital ring oscillator 400, according to one embodiment. The circuit of FIG. 4 is the same as FIGS. 3A and 3B, with the addition of delay elements 410, 411 between state nodes 260, 261 and corresponding inputs 250, 251. The DRO 400 is composed of the header transistors 211 and 231, the cross-coupled inverters 300 and 310, the footer transistors 221 and 241, and the delay elements 410 and 411. Although not depicted, the transistors 212, 222, 232, and 242 may be included in the DRO 400 to improve the voltage stability of the DRO 400. The unit cell 200 of FIG. 2A may be transformed into a digital ring oscillator by inserting delay elements 410 and 411 at the gates of the transistors 211, 221, 231, and 241 as depicted in FIG. 4. The delay elements 410 and 411 stabilize the DRO 400 (e.g., the delay elements maintain the Barkhausen criterion). The delay elements 410 and 411 create a delay between the state nodes 260 and 261 and the gates of the PMOS header transistors 210 and 230 and NMOS footer transistors 220 and 240. In particular, the delay element 410 is located between the state node 260, and the input 250 and the delay element 411 is located between the state node 261 and the input 251. A sensor block 130 may include the DRO 400. The toggling states of one or more of the internal nodes 260 and 261 of the DRO 400 may contribute to an oscillatory digital signal output by the DRO 400 (e.g., output as measured at either of the internal nodes 260 or 261). This oscillatory digital signal may be included in the data 156 output by the sensor blocks 130.

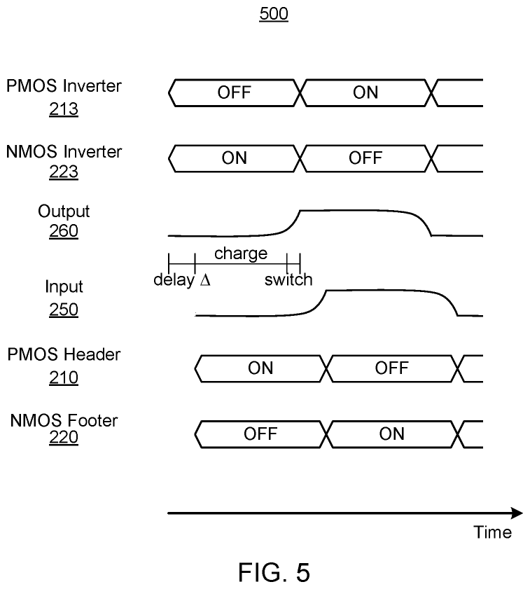

FIG. 5 depicts a timing diagram of the inputs, outputs, and transistor states, of the DRO 400, in accordance with at least one embodiment. In the timing diagram 500, the state node 260, which is labeled as “output” in FIG. 5, begins at logic low. In this state, the PMOS inverter transistor 213 is OFF and the NMOS inverter transistor 223 is ON. This connects the state node 260 to ground. After a delay A enabled by the delay element 410, the value of the state node 260 is reflected at the input 250. The ‘0’ at the input 250 causes the PMOS header 210 to switch ON and the NMOS footer 220 to switch OFF. This sets up a leakage path from VDD through the PMOS header 210. Leaking current from VDD through the PMOS header 210 and the OFF PMOS 213 starts to charge the node 260, as indicated by the “charge” label in FIG. 5. When the state node 260 reaches a threshold point, the bistability of the cross-coupled inverters causes the same node 260 to switch from ‘0’ to ‘1’ As indicated by the “switch” label in FIG. 5. This process then repeats, but discharging the state node 260.

The complementary state node 261 operates similarly, but in the complementary state. Node 261 charges when node 260 discharges, and vice versa.

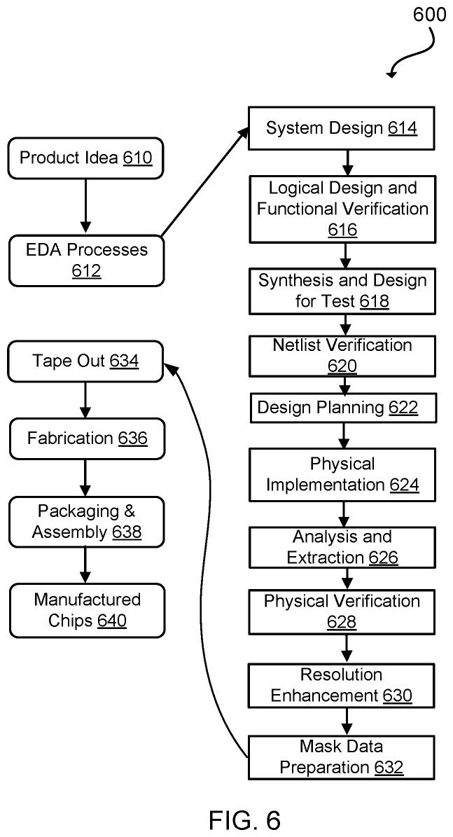

FIG. 6 illustrates an example set of processes 600 used during the design, verification, and fabrication of an article of manufacture such as an integrated circuit to transform and verify design data and instructions that represent the integrated circuit. Each of these processes can be structured and enabled as multiple modules or operations. The term ‘EDA’ signifies the term ‘Electronic Design Automation.’ These processes start with the creation of a product idea 610 with information supplied by a designer, information which is transformed to create an article of manufacture that uses a set of EDA processes 612. When the design is finalized, the design is taped-out 634, which is when artwork (e.g., geometric patterns) for the integrated circuit is sent to a fabrication facility to manufacture the mask set, which is then used to manufacture the integrated circuit. After tape-out, a semiconductor die is fabricated 637 and packaging and assembly processes 638 are performed to produce the finished integrated circuit 640.

Specifications for a circuit or electronic structure may range from low-level transistor material layouts to high-level description languages. A high-level of representation may be used to design circuits and systems, using a hardware description language (‘HDL’) such as VHDL, Verilog, SystemVerilog, SystemC, MyHDL or OpenVera. The HDL description can be transformed to a logic-level register transfer level (‘RTL’) description, a gate-level description, a layout-level description, or a mask-level description. Each lower representation level that is a more detailed description adds more useful detail into the design description, for example, more details for the modules that include the description. The lower levels of representation that are more detailed descriptions can be generated by a computer, derived from a design library, or created by another design automation process. An example of a specification language at a lower level of representation language for specifying more detailed descriptions is SPICE, which is used for detailed descriptions of circuits with many analog components. Descriptions at each level of representation are enabled for use by the corresponding tools of that layer (e.g., a formal verification tool). A design process may use a sequence depicted in FIG. 6. The processes described by be enabled by EDA products (or tools).

During system design 614, functionality of an integrated circuit to be manufactured is specified. The design may be optimized for desired characteristics such as power consumption, performance, area (physical and/or lines of code), and reduction of costs, etc. Partitioning of the design into different types of modules or components can occur at this stage.

During logic design and functional verification 616, modules or components in the circuit are specified in one or more description languages and the specification is checked for functional accuracy. For example, the components of the circuit may be verified to generate outputs that match the requirements of the specification of the circuit or system being designed. Functional verification may use simulators and other programs such as testbench generators, static HDL checkers, and formal verifiers. In some embodiments, special systems of components referred to as ‘emulators’ or ‘prototyping systems’ are used to speed up the functional verification.

During synthesis and design for test 618, HDL code is transformed to a netlist. In some embodiments, a netlist may be a graph structure where edges of the graph structure represent components of a circuit and where the nodes of the graph structure represent how the components are interconnected. Both the HDL code and the netlist are hierarchical articles of manufacture that can be used by an EDA product to verify that the integrated circuit, when manufactured, performs according to the specified design. The netlist can be optimized for a target semiconductor manufacturing technology. Additionally, the finished integrated circuit may be tested to verify that the integrated circuit satisfies the requirements of the specification.

During netlist verification 620, the netlist is checked for compliance with timing constraints and for correspondence with the HDL code. During design planning 622, an overall floor plan for the integrated circuit is constructed and analyzed for timing and top-level routing.

During layout or physical implementation 624, physical placement (positioning of circuit components such as transistors or capacitors) and routing (connection of the circuit components by multiple conductors) occurs, and the selection of cells from a library to enable specific logic functions can be performed. As used herein, the term ‘cell’ may specify a set of transistors, other components, and interconnections that provides a Boolean logic function (e.g., AND, OR, NOT, XOR) or a storage function (such as a flipflop or latch). As used herein, a circuit ‘block’ may refer to two or more cells. Both a cell and a circuit block can be referred to as a module or component and are enabled as both physical structures and in simulations. Parameters are specified for selected cells (based on ‘standard cells’) such as size and made accessible in a database for use by EDA products.

During analysis and extraction 626, the circuit function is verified at the layout level, which permits refinement of the layout design. During physical verification 628, the layout design is checked to ensure that manufacturing constraints are correct, such as DRC constraints, electrical constraints, lithographic constraints, and that circuitry function matches the HDL design specification. During resolution enhancement 630, the geometry of the layout is transformed to improve how the circuit design is manufactured.

During tape-out, data is created to be used (after lithographic enhancements are applied if appropriate) for production of lithography masks. During mask data preparation 632, the ‘tape-out’ data is used to produce lithography masks that are used to produce finished integrated circuits.

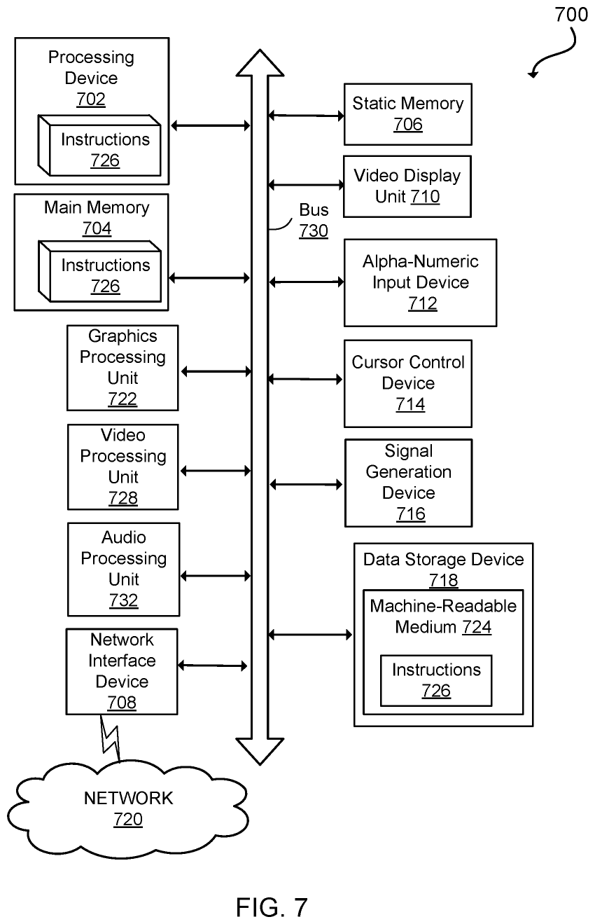

A storage subsystem of a computer system (such as computer system 700 of FIG. 7) may be used to store the programs and data structures that are used by some or all of the EDA products described herein, and products used for development of cells for the library and for physical and logical design that use the library.

FIG. 7 illustrates an example machine of a computer system 700 within which a set of instructions, for causing the machine to perform any one or more of the methodologies discussed herein, may be executed. In alternative implementations, the machine may be connected (e.g., networked) to other machines in a LAN, an intranet, an extranet, and/or the Internet. The machine may operate in the capacity of a server or a client machine in client-server network environment, as a peer machine in a peer-to-peer (or distributed) network environment, or as a server or a client machine in a cloud computing infrastructure or environment.

The machine may be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 700 includes a processing device 702, a main memory 704 (e.g., read-only memory (ROM), flash memory, dynamic random access memory (DRAM) such as synchronous DRAM (SDRAM), a static memory 706 (e.g., flash memory, static random access memory (SRAM), etc.), and a data storage device 718, which communicate with each other via a bus 730.

Processing device 702 represents one or more processors such as a microprocessor, a central processing unit, or the like. More particularly, the processing device may be complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 702 may also be one or more special-purpose processing devices such as an application specific integrated circuit (ASIC), a field programmable gate array (FPGA), a digital signal processor (DSP), network processor, or the like. The processing device 702 may be configured to execute instructions 726 for performing the operations and steps described herein.

The computer system 700 may further include a network interface device 708 to communicate over the network 720. The computer system 700 also may include a video display unit 710 (e.g., a liquid crystal display (LCD) or a cathode ray tube (CRT)), an alphanumeric input device 712 (e.g., a keyboard), a cursor control device 714 (e.g., a mouse), a graphics processing unit 722, a signal generation device 716 (e.g., a speaker), graphics processing unit 722, video processing unit 728, and audio processing unit 732.

The data storage device 718 may include a machine-readable storage medium 724 (also known as a non-transitory computer-readable medium) on which is stored one or more sets of instructions 726 or software embodying any one or more of the methodologies or functions described herein. The instructions 726 may also reside, completely or at least partially, within the main memory 704 and/or within the processing device 702 during execution thereof by the computer system 700, the main memory 704 and the processing device 702 also constituting machine-readable storage media.

In some implementations, the instructions 726 include instructions to implement functionality corresponding to the present disclosure. While the machine-readable storage medium 724 is shown in an example implementation to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine and the processing device 702 to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm may be a sequence of operations leading to a desired result. The operations are those requiring physical manipulations of physical quantities. Such quantities may take the form of electrical or magnetic signals capable of being stored, combined, compared, and otherwise manipulated. Such signals may be referred to as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the present disclosure, it is appreciated that throughout the description, certain terms refer to the action and processes of a computer system, or similar electronic computing device, that manipulates and transforms data represented as physical (electronic) quantities within the computer system's registers and memories into other data similarly represented as physical quantities within the computer system memories or registers or other such information storage devices.

The present disclosure also relates to an apparatus for performing the operations herein. This apparatus may be specially constructed for the intended purposes, or it may include a computer selectively activated or reconfigured by a computer program stored in the computer. Such a computer program may be stored in a computer readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various other systems may be used with programs in accordance with the teachings herein, or it may prove convenient to construct a more specialized apparatus to perform the method. In addition, the present disclosure is not described with reference to any particular programming language. It will be appreciated that a variety of programming languages may be used to implement the teachings of the disclosure as described herein.

The present disclosure may be provided as a computer program product, or software, that may include a machine-readable medium having stored thereon instructions, which may be used to program a computer system (or other electronic devices) to perform a process according to the present disclosure. A machine-readable medium includes any mechanism for storing information in a form readable by a machine (e.g., a computer). For example, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing disclosure, implementations of the disclosure have been described with reference to specific example implementations thereof. It will be evident that various modifications may be made thereto without departing from the broader spirit and scope of implementations of the disclosure as set forth in the following claims. Where the disclosure refers to some elements in the singular tense, more than one element can be depicted in the figures and like elements are labeled with like numerals. The disclosure and drawings are, accordingly, to be regarded in an illustrative sense rather than a restrictive sense.

What is claimed is:

1. A non-transitory computer readable storage medium comprising a stored electronic representation of a digital ring oscillator, the digital ring oscillator comprising:
a pair of cross-coupled inverters, wherein an input of each of the inverters is coupled to an output of the other inverter at one of two complementary state nodes;
two header transistors coupled between a supply voltage and the inverters, wherein the header transistors gate a connection of the supply voltage to the inverters;
two footer transistors coupled between the inverters and ground, wherein the footer transistors gate a connection of the inverters to ground;
delay elements coupled between the state nodes and gates of the header and footer transistors; and
wherein the state nodes toggle states as a result of leakage current gated by the header transistors from the supply voltage through the inverters to the state nodes, and as a result of the leakage current gated by the footer transistors from the state nodes through the inverters to ground; a frequency of the toggling is a function of the leakage current and the leakage current is a function of a temperature of the digital ring oscillator.

2. The non-transitory computer readable storage medium of claim 1, wherein the two complementary state nodes are configured to:
charge to a logic high state in response to the output of one of the delay elements being a logic low state; and
discharge to a logic low state in response to the output of the other delay elements being a logic high state.

3. The non-transitory computer readable storage medium of claim 1, wherein the cross-coupled inverters, the header transistors, and the footer transistors comprise:
a first PMOS header transistor having a source coupled to the supply voltage;
a first PMOS inverter transistor having a source coupled to a drain of the first PMOS header transistor;
a first NMOS inverter transistor having a drain coupled to a drain of the first PMOS inverter transistor;
a first NMOS footer transistor having a drain coupled to a source of the first NMOS inverter transistor;
a second PMOS header transistor having a source coupled to the supply voltage;
a second PMOS inverter transistor having a source coupled to a drain of the second PMOS header transistor;
a second NMOS inverter transistor having a drain coupled to a drain of the second PMOS inverter transistor; and
a second NMOS footer transistor having a drain coupled to a source of the second NMOS inverter transistor.

4. The non-transitory computer readable storage medium of claim 3, wherein:
the two state nodes comprise a first state node and a second state node;
the first state node is coupled to the drains of the first PMOS and NMOS inverter transistors and to gates of the second PMOS and NMOS inverter transistors;
the second state node is coupled to the drains of the second PMOS and NMOS inverter transistors and to gates of the first PMOS and NMOS inverter transistors;
the delay elements comprise a first delay element and a second delay element;
the first delay element is coupled between the first state node and gates of the first header and footer transistors; and
the second delay element is coupled between the second state node and gates of the second header and footer transistors.

5. The non-transitory computer readable storage medium of claim 3, wherein the digital ring oscillator further comprises:
a third PMOS header transistor coupled in parallel to the first PMOS header transistor;
a fourth PMOS header transistor coupled in parallel to the second PMOS header transistor, wherein a drain of the third PMOS header transistor is coupled to a gate of the fourth PMOS header transistor and a drain of the fourth PMOS header transistor is coupled to a gate of the third PMOS header transistor;
a third NMOS footer transistor coupled in parallel to the first NMOS footer transistor; and
a fourth NMOS footer transistor coupled in parallel to the second NMOS footer transistor, wherein a drain of the third NMOS footer transistor is coupled to a gate of the fourth NMOS footer transistor and a drain of the fourth NMOS footer transistor is coupled to a gate of the third NMOS footer transistor.

6. The non-transitory computer readable storage medium of claim 1, wherein the digital ring oscillator has an area smaller than an area of a flip-flop on a same integrated circuit die as the digital ring oscillator.

7. The non-transitory computer readable storage medium of claim 1, wherein the digital ring oscillator comprises at most twelve transistors and the delay elements.

8. The non-transitory computer readable storage medium of claim 1, wherein the representation of the digital ring oscillator is a library cell.

9. An integrated circuit die comprising:
a plurality of sensor blocks distributed at different locations on the die, wherein the sensor blocks comprise digital ring oscillators that produce oscillatory digital signals with frequencies that vary as a function of temperature; and
a controller coupled to the sensor blocks, wherein the controller receives the oscillatory digital signals and controls operation of the integrated circuit die based on temperatures indicated by the frequencies of the oscillatory digital signals.

10. The integrated circuit die of claim 9, wherein the controller is further configured to compare the oscillatory digital signals to a reference frequency.

11. The integrated circuit die of claim 9, wherein the controller is a dynamic voltage and frequency scaling (DVFS) controller.

12. The integrated circuit die of claim 9, wherein the number of sensors blocks on the integrated circuit die is greater than the number of controllers on the integrated circuit die.

13. The integrated circuit die of claim 9, wherein the controller is further configured to disable voltage throttling based on the temperatures.

14. The integrated circuit die of claim 9, wherein the controller is further configured to determine a difference between frequencies of the digital oscillatory signals of the digital ring oscillators, and the difference indicates the temperatures.

15. The integrated circuit die of claim 9, wherein the temperature indications are insensitive to supply voltage variations and process variations.

16. A method comprising:
receiving oscillatory digital signals from a plurality of sensor blocks on an integrated circuit die, wherein frequencies of the oscillatory digital signals vary as a function of temperature; and
controlling operation of circuitry on the integrated circuit die based on temperatures indicated by the frequencies of the oscillatory digital signals.

17. The method of claim 16, wherein controlling the operation of the integrated circuit die comprises controlling one or more of an energy-efficient core, a performance core, a computer processing unit (CPU), an input-output (IO) system, or a neural engine.

18. The method of claim 16, further comprising determining differential temperature measurements between oscillatory digital signals of pairs of sensor blocks.

19. The method of claim 18, further comprising:
determining an on-die profile of the temperatures on the integrated circuit die; and
identifying local hot-spots on the integrated circuit die using the on-die profile.

20. The method of claim 19, further comprising:
in response to determining a temperature of the identified local hot-spots is below a threshold temperature, disabling voltage throttling of circuitry at the local hot-spots.
